(19) United States
(12) Patent Application Publication
(10) Pub. No.: US 2010/0134126 A1
(43) Pub. Date: Jun. 3, 2010

(54) PROBE AND METHOD FOR MANUFACTURING THE SAME

(75) Inventors: Ki-Pil Hong, Yongin-si (KR); Jong-Hyeon Chae, Yongin-si (KR); Hac-Ju Lee, Yongin-si (KR); Young-Gun Park, Yongin-si (KR)

Correspondence Address: PEARNE & GORDON LLP, 1801 EAST 9TH STREET, SUITE 1200, CLEVELAND, OH, 44114-3108, US

(73) Assignees: M2N, INC., Yongin-si, Gyeonggi-do (KR); SECRON CO., LTD., Cheonan-city, Chungeheongnam-do (KR)

(21) Appl. No.: 11/816,852

(22) PCT Filed: Mar. 31, 2005
(86) PCT No.: PCT/KR2005/000957

§ 371 Date: Aug. 22, 2007

(30) Foreign Application Priority Data
Feb. 22, 2005 (KR) 10-2005-0014701
Mar. 29, 2005 (KR) 10-2005-0026116

(51) Int. Cl. G01R 31/02; H01L 21/768

(52) U.S. Cl. 324/757; 438/666; 257/E21.575

(57) ABSTRACT

A probe for making electric contact with a contact target includes a first part (10) including a first base portion (15) and a socket portion (17) formed on the first base portion; and a second part including (20) a second base portion (25) and a plug portion (21) formed on the second base portion. And the plug portion is removably coupled to the socket portion.

### TECHNICAL FIELD

The present invention relates to a probe used in a semiconductor inspection equipment and method for manufacturing the same; and, more particularly, to a probe which is capable of making it easy to repair or exchange its damaged or broken probe tip for a new one, and method for manufacturing the same.

### BACKGROUND ART

Generally, a probe card including a plurality of probe tips refers to a device for delivering test signals of a semiconductor inspection equipment onto contact locations of a wafer or substrate and then returned electrical signals from the wafer or substrate to the semiconductor inspection equipment by establishing electrical communication between the wafer or substrate and the semiconductor inspection equipment to test the performance of semiconductor devices, such as a semiconductor memory, a display or the like during or after the manufacture thereof.

In today's semiconductor technology, the technology for miniaturizing semi-conductor devices is more and more progressing. In this context, the size of a chip pad of a wafer is also being reduced and, accordingly, extensive research and development for miniaturizing probe tips to be in contact with the pad is underway.

### DISCLOSURE OF INVENTION

### Technical Problem

However, the conventional probe card has a disadvantage in that its broken or damaged probe tips cannot be replaced with new ones or the cost for repairing the broken or damaged probe tips is considerably expensive.

### Technical Solution

It is, therefore, an object of the present invention to provide a probe and method for manufacturing the same capable of an easy repair or exchange of a probe tip by forming a socket structure in the probe divided into upper and lower parts.

It is another object of the present invention to provide a method for manufacturing a probe which is capable of an easy repair or exchange of a probe tip by forming a socket structure in the probe.

It is still another object of the present invention to provide a contact structure (or probe card) which is capable of simplifying its manufacturing processes, thereby improving its yield and making it easy to manufacture it.

In accordance with one aspect of the invention, there is provided a probe for making electric contact with a contact target, including: a first part including a first base portion and a socket portion formed on the first base portion; and a second part including a second base portion and a plug portion formed on the second base portion, wherein the plug portion is removably coupled to the socket portion.

In accordance with another aspect of the invention, there is provided a method for manufacturing a probe, including the steps of: forming a conductive layer on a semi-conductor substrate; forming on the conductive layer a pattern layer in which a first group of openings, each being formed in a shape of a first part having a socket portion, and a second group of openings, each being formed in a shape of a second part having a plug portion, are formed, the first group of openings being connected to a first tree opening, the second group of openings being connected to a second tree opening; forming a probe structure on an upper surface of the conductive layer exposed through the pattern layer by performing a plating process; and removing the pattern layer, the semiconductor substrate and the conductive layer.

In accordance with still another aspect of the invention, there is provided a method for manufacturing a probe, including the steps of: forming a conductive layer on a semiconductor substrate; forming on the conductive layer a pattern layer which has a first group of patterns, each being formed in a shape of a first part having a socket portion, and a second group of patterns, each being formed in a shape of a second part having a plug portion, the first group of patterns being connected to a first tree patterns, the second group of patterns being connected to a second tree pattern; forming a probe structure by patterning the conductive layer covered by the pattern layer; and removing the pattern layer and the semiconductor substrate, wherein the pattern layer serves as an etch mask when the conductive layer is patterned.

In accordance with still another aspect of the invention, there is provided a method for manufacturing a contact module, including the steps of: inserting a first part of a probe, having a first base portion, a socket portion formed on the first base portion, and a second part of the probe, having a second base portion, a plug portion formed on the second base portion and a connection pin formed on the second base portion, into an upper and a lower portion of a contact hole of a contact substrate, respectively so that the first part is removably coupled to the second part; and mounting a through hole space transformer on the connection pin of the probe.

### Advantageous Effects

As described above, in accordance with the present invention, the probe includes a first part having a socket portion and a second part having a plug portion, so that the first part is removably connected to the second part to form the probe. Therefore, in case where a probe tip of the probe is severely contaminated, damaged or broken, the part having such a probe tip can be repaired or exchanged for new one by removing the part having such a bad probe and then connecting the new one to the other part. Accordingly, a repair or exchange of a probe tip can be made readily and cost-effectively.

Further, in accordance with the present invention, the probe tip is connected to a base portion of the probe by an elastic portion having a springable-shape and a supplementary pattern. Therefore, a pressure exerted on the probe tip when the probe makes contact with a wafer chip pad can be cushioned by the elastic portion. And the supplementary pattern formed between the elastic portion and the base portion can prevent a stress concentration in the probe tip and the elastic portion. Accordingly, breaking or damaging of the probe from the pressure exerted on the probe tip can be avoided.

Moreover, in accordance with the present invention, the first part and the second part of the probe have aligning pins formed on their base portions, respectively. Therefore, the first and the second part can be aligned precisely and easily with respect to a contact substrate without using any equipment for aligning the probe tips on the contact substrate. Accordingly, costs and times spent on aligning the probe tips can be saved and precise setting of the probe tips on the wafer chip pads undergoing testing can be accomplished.

Further, in accordance with the present invention, the positions of the socket portion and the aligning pin with respect to the elastic portion, i.e., a probe tip, can be modified, and the position of the other aligning pin with respect to the plug portion can be modified. Therefore, by forming first contact holes for receiving a socket portion and a plug portion in the contact substrate in such a way as to be arranged in a zigzag manner, a gap between the first contact holes is increased and a vertical distance therebetween is reduced while the probe tips are arranged in a straight line. In addition, by forming second contact holes for receiving the aligning pins in the contact substrate in such a way as to be arranged in a zigzag manner, a gap between the second contact holes is increased and a vertical distance therebetween is reduced. Accordingly, the pitch between the probe tips can be reduced to such an extent that the contact structure can be applied to a 64 or higher para probe card requiring a fine pitch.

In addition, in accordance with the present invention, the first part having a probe tip is inserted into the contact hole of the contact substrate from a first surface of the contact substrate and the second part is inserted into the contact hole of the contact substrate from a second surface of contact substrate. And the first part is removably connected to the second part in the contact hole. Therefore, even if the probe tip is broken or damaged while being used, its repair can be made easily and cost-effectively by removing only the upper part with the broken or damaged probe tip and then inserting a new one.

Furthermore, in accordance with the present invention, the position of the connection pins with respect to the plug portions or the socket portions can be modified. Accordingly, upper pads of a space transformer with which the connection pins of the probe make contact are allowed to have a larger degree of freedom with respect to their arrangement. This allows the pad arrangement pitches on the upper surface of the space transformer to correspond directly with the arrangement of the connection pins. Thus, contacts in the stacked body of the space transformer can run straight through the body. As a result, the space transformer for connecting the connection pins of the probes with the pogo pins can be manufactured easily and have good electrical characteristics.

### BRIEF DESCRIPTION OF THE DRAWINGS

The above and other objects and features of the present invention will become apparent from the following description of preferred embodiments given in conjunction with accompanying drawings, in which:

FIG. 1 illustrates a top plan view of a probe in accordance with a first preferred embodiment of the present invention;

FIG. 2 illustrates a top plan view of a probe in accordance with a second preferred embodiment of the present invention;

FIG. 3 illustrates a top plan view of a probe in accordance with a third preferred embodiment of the present invention;

FIG. 4 shows a top plan view of a socket portion in accordance with a modified embodiment;

FIGS. 5 to 13 illustrate a method for manufacturing a probe performed in accordance with a preferred embodiment of the present invention;

FIG. 14 shows a perspective view of a unprocessed end portion of a probe tip;

FIG. 15 presents a perspective view of a processed end portion of the probe tip;

FIG. 16 provides a perspective view of a contact substrate in accordance with a preferred embodiment of the present invention;

FIGS. 17 to 25 set forth a manufacturing process of the contact substrate performed in accordance with a preferred embodiment of the present invention;

FIGS. 26 to 29 describe perspective and partial cross-sectional views of the contact structure in accordance with preferred embodiments of the present invention;

FIG. 30 shows a perspective view of a through hole space transformer in accordance with a preferred embodiment of the present invention;

FIGS. 31 to 33 illustrate a method for manufacturing the through hole space transformer in accordance with a preferred embodiment of the present invention; and

FIG. 34 offers an exploded, perspective view of the contact module which includes the contact substrate, the through hole space transformer and a pogo pin block.

### BEST MODE FOR CARRYING OUT THE INVENTION

Hereinafter, preferred embodiments of the present invention will be described in detail with reference to the accompanying drawings so that they can be easily implemented by those skilled in the art of the present invention.

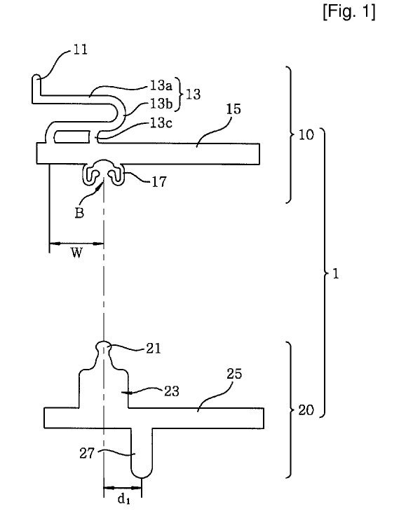

Referring to FIG. 1, there is illustrated a top plan view of a probe in accordance with a first preferred embodiment of the present invention. As shown in FIG. 1, the probe 1 is divided into an upper part 10 and a lower part 20 which are made of a conductive material, e.g., a metal, capable of conducting electricity.

The upper part 10 of the probe 1 includes a upper base portion 15 which is formed into a straight cantilever shape to have a flat upper surface and a flat lower surface; an elastic portion 13 formed on the upper surface of the base portion into a springable-shape; a probe tip 11 which is formed vertically at a free end of the elastic portion 13 for making contact with a wafer chip pad as a contact target; and a socket portion 17 which is formed on the lower surface of the upper base portion 15 for serving as an electrical receptacle.

Further, the elastic portion 13, cushioning the pressure exerted on the probe tip 11 when the probe tip 11 being brought into the contact with the wafer chip pad, is formed with a curved portion 13b formed on the upper surface of the upper base portion 15 into an S-shape, and a bar portion 13a extended horizontally or slantingly from a free end of the curved portion 13b. And the elastic portion 13 is additionally connected to the first base portion 15 via a supplementary pattern 13c formed between the curved portion 13b and the upper surface of the upper base portion 15, so that the stress concentration in the probe tip 11 and the elastic portion 13 can be prevented.

The lower part 20 of the probe 1 includes a second base portion 25 which is formed into a straight cantilever shape to have a flat upper surface and a flat lower surface; a plug portion 23 which is formed on the first surface of the lower base portion 25 for being removably inserted into the socket portion 17 of the upper part 10; and a connection pin 27 which is formed vertically on the lower surface of the second base portion 25 for making contact with a space transformer, such as a multi-layer ceramic (MLC) or the like.

Further, the plug portion 23 is provided with an engaging protrusion 21 at its end and the socket portion 17 is provided with a coupling groove B for being removably coupled to the engaging protrusion 21 of the plug portion 23. So the upper portion 10 can be combined with and detached from the lower portion 20 by inserting or extracting the plug portion 23 into or from the socket portion 17. Therefore, in case where any probe tip 11 of a probe card in a wafer tester or a prober is contaminated, damaged or broken during a semiconductor inspection, only the upper part 10 having such probe tip 11 can be repaired or exchanged for a new one instead of replacing the entire probe card with new one.

Further, when the probe tip 11 is brought into contact with a wafer chip pad, the pressure exerted on the probe tip 11 can be cushioned by the elastic portion 13 connected to the probe tip 11, and the stress concentration in the probe tip 11 and the elastic portion 13 can be avoided by forming the supplementary pattern 13c between the upper surface of the upper base portion 15 and the elastic portion 13. Therefore, a plastic deformation of the probe tip 11 and/or the elastic portion 13 can be avoided.

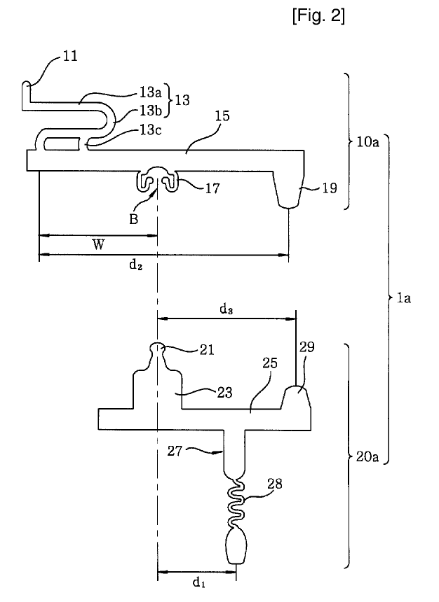

FIG. 2 illustrates a top plan view of a probe in accordance with a second preferred embodiment of the present invention, wherein like parts to those of the first preferred embodiment are presented by like reference numerals and detailed description thereof will be omitted for simplicity.

Referring to FIG. 2, the probe 1a in accordance with the second preferred embodiment is divided into an upper part 10a and a lower part 20a that are made of a conductive material, e.g., a metal, capable of conducting electricity, as in the first preferred embodiment.

The probe 1a is different from the probe 1 of the first preferred embodiment in that the upper part 10a further includes an aligning pin 19 formed vertically on a lower surface of an upper base portion 15 and that the lower part 20a further includes an aligning pin 29 formed vertically on an upper surface of an lower base portion 25 and an intermediate elastic portion 28 formed in the connection pin 27.

The aligning pins 19 and 29 facilitate the alignment of the upper part 10a and the lower part 20a in a contact substrate (described later). And the intermediate elastic portion 28 cushions the pressure exerted on the connection pin 27 when the it is brought into contact with the MLC or the like.

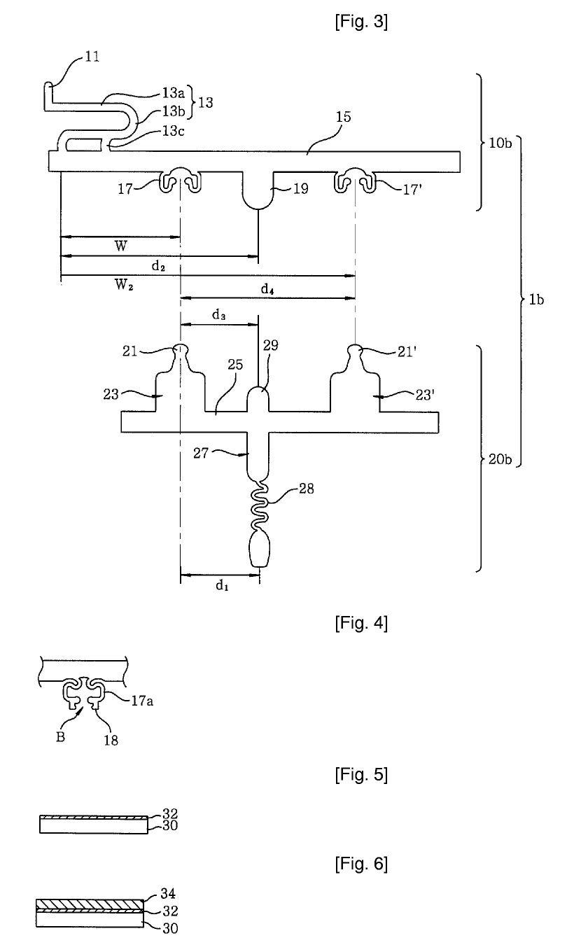

FIG. 3 illustrates a top plan view of a probe in accordance with a third preferred embodiment of the present invention, wherein like parts to those of the second preferred embodiment are presented by like reference numerals and detailed description thereof will be omitted for simplicity.

Referring to FIG. 3, the probe 1b in accordance with the third preferred embodiment is divided into an upper part 10b and a lower part 20b that are made of a conductive material, e.g., a metal, capable of conducting electricity, as in the second preferred embodiment.

The probe 1b is different from the probe 1a of the second preferred embodiment in that the upper part 10b further includes an additional socket portion 17′ formed on a rear portion of the lower surface of the upper base portion 15, and that the lower part 20b further includes an additional plug portion 23′ formed on a rear portion of the upper surface of the lower base portion 25.

Since the socket portions 17 and 17′ are disposed in a front portion and the rear portion of the upper base portion 15, respectively and the plug portions 23 and 23′ are disposed in a front portion and the rear portion of the lower base portion 25, the stronger connection is made between the upper part 10b and the lower part 20b.

Further, in the first, second and third preferred embodiment, the positions W and W2 of the socket portions 17 and 17′ and the positions d2 of the aligning pin 19 with respect to the elastic portion 13 can be modified. Additionally, the positions d1 of the connection pin 27, the positions d3 of the aligning pin 29 and the position d4 of the additional plug portion 23′ with respect to the plug portion 23 can also be modified. Moreover the socket portion 17a can be replaced with a socket portion 17a shown in FIG. 4. The socket portion 17a is provided with a guide lip 18 for guiding the engaging protrusion 21 of the plug member 23 into the engaging groove B.

Further, in the first, second and third preferred embodiment, although the upper part and the lower port are configured to have the socket portion and the plug portion, respectively, the upper part and the lower part can be configured to have the opposite portions. In other words, the plug portion and the socket portion are formed on the upper base portion 15 and the lower base portion 25, respectively.

Hereinafter, methods for manufacturing a probe performed in accordance with a preferred embodiment of the present invention, which employs microelectro-mechanical system (MEMS) technologies, will be described with reference to FIGS. 5 to 13.

First, as shown in FIG. 5, a metal (e.g., Ni, Au or the like) or metal alloy layer is formed as a conductive layer 32 on a 100 silicon substrate 30, i.e., a semiconductor substrate, by using a physical vapor deposition (PVD) process. Then, a photoresist layer 34 is coated on the conductive layer 32, for example, by a spin coating process, as shown in FIG. 6.

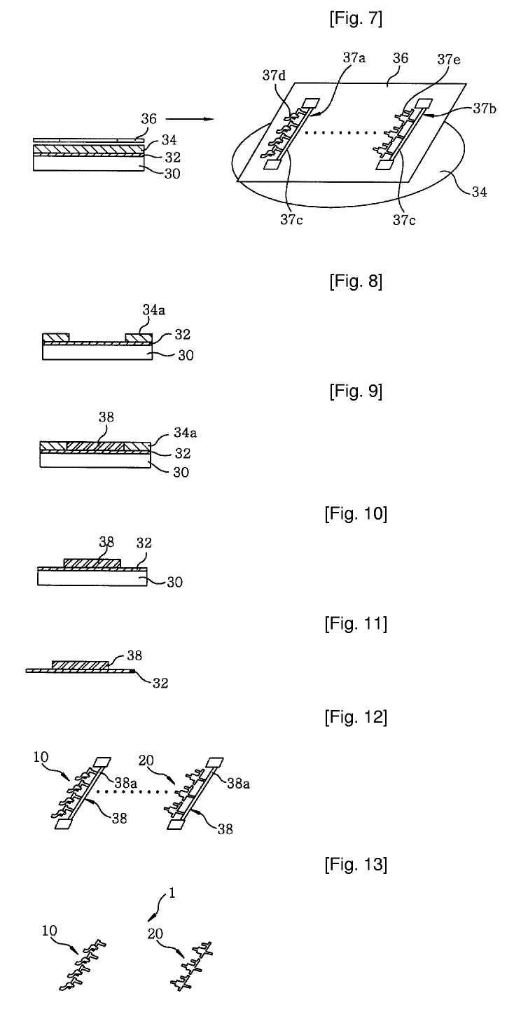

Next, as shown in FIG. 7, a mask 36 is aligned on the photoresist layer 34 along the 100 crystal direction of the silicon substrate 30 and, then, the photoresist layer 34 is exposed to a light by using a ultraviolet exposure unit. In the mask 36, a plurality of first patterns 37a and a plurality of second patterns 37b are defined. Each of the first patterns 37a has a tree pattern 37c and a plurality of upper part patterns 37d having the shape of the upper part 10, 10a or 10b, and being connected to the tree pattern 37c and each of the second patterns 37b has a tree pattern 37c and a plurality of lower part patterns 37e having the shape of the lower part 20, 20a or 20b and being connected to the tree pattern 37c.

Thereafter, a developing process is performed on the exposed photoresist layer 34, so that a patterned photoresist layer 34a is formed as shown in FIG. 8.

In the ensuing step shown in FIG. 9, by performing a plating process a plurality of probe structures 38 are formed on an upper surface of the conductive layer 32 exposed through the patterned photoresist layer 34a. Following the plating process, upper surfaces of the probe structures 38 are planarized by a chemical mechanical polishing (CMP) process.

Next, the patterned photoresist layer 34a is removed by an ashing process or a wet type removal process as shown in FIG. 10 and, then, the silicon substrate 30 is removed by a first wet etching process, so that only the probe structures 38 and the conductive layer 32 formed thereunder are left as shown in FIG. 11.

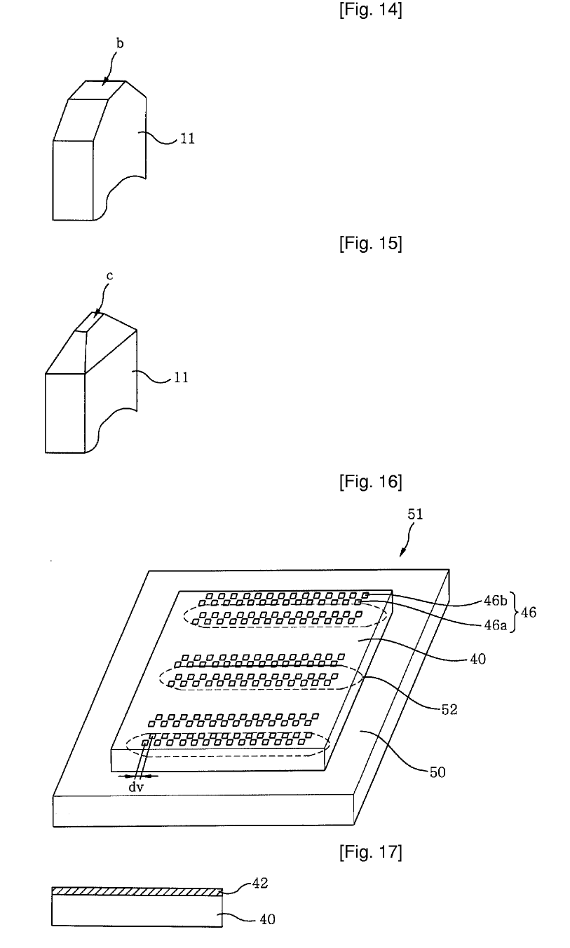

Next, as shown in FIG. 12, the conductive layer 32 is removed by a second etching process, so that the probe structures 38, each being constituted by a plurality of, for example, the upper or lower parts (or sub-structures) 10 or 20 connected to a tree structure 38a, are separated from each other. Then, end portions of the probe tips of the upper parts 10, 10a or 10b in the same probe structure 38, which have a two dimensional trapezoid-shape end portion b as shown in FIG. 14, is processed to have a truncated pyramid-shape end portion c as shown in FIG. 15 by performing a wet etching process, a mechanical grinding process or the like.

Finally, as shown in FIG. 13, the upper and lower parts 10 and 20 are separated from their trees 38a by using a cutter or the like, completing the manufacture of the probe.

Further, the probe structure can be formed by patterning the conductive layer 32 by an etching process after forming a patterned photoresist layer inversely on the conductive layer (i.e. by using the photoresist pattern as an etch mask). Moreover, the removal sequence of the silicon substrate 30 and the conductive layer 32 may be changed. That is, the silicon substrate 30 is removed after the conductive layer 32 is removed while the portion thereof below the probe structure 38 remains unremoved.

Since the method for manufacturing a probe performed in accordance with the preferred embodiment of the present invention does not include the steps of depositing and removing a sacrificial layer, such as a silicon oxide (SiO₂) film or the like, the etching loss occurring in a probe tip during the removing process of the sacrificial layer can be minimized, wherein the etching loss occurs by a reaction between a conductive layer material (e.g., Ni or the like) of the probe tip and an etching solution for removing the sacrificial layer during a conventional sacrificial layer removal process for manufacturing a probe.

In the prior art, each probe is separately manufactured on a substrate and then the individual probes are separated from the substrate by using a sticky tape. Thereafter, an end portion of the probe tip of the probe is processed one by one. Therefore, there have been problems, such as, contamination, deformation occurring when the probe is separated from the tape, and taking too long a period of time to process the end portions of the probe tips. On the other hand, in the present invention, a group of the upper parts and a group of the lower parts are connected to the trees, respectively, and the probe tips of the upper parts connected to the same tree are processed simultaneously to have the truncated pyramid-shape end portions. And, then, the upper parts are separated from the tree. Therefore, unlike the prior art in which probe tips are processed one by one and the sticky tape is used, a manufacturing time can be reduced and a manufacturing yield can be improved.

Hereinafter, a contact substrate in which a plurality of the probes 1, 1a or 1b are installed will be described with reference to FIG. 16.

Referring to FIG. 16, there is illustrated a perspective view of the contact substrate in accordance with a preferred embodiment of the present invention. The contact substrate 51 for installing a plurality of the probes therein includes a single layer silicon substrate 40 which has a plurality of contact holes 46 formed therein, and a support substrate 50 for reinforcing the silicon substrate 40. The contact holes 46 are provided with first contact holes 46a for receiving the socket portion and the plug portion of the probe and second contact holes 46b for receiving the aligning pins of the probe. The first contact holes 46a and the second contact holes 46b are arranged in a zigzag manner. Further, an insulating thin film, e.g., a silicon oxide (SiO₂) film or the like, is deposited on an upper surface of the silicon substrate 40 and inner surface of contact holes 46 (see FIG. 21).

The supporting substrate 50 having several elongated openings 52 formed therein by a mechanical processing such as a milling or the like is disposed under the silicon substrate 40, wherein each opening 52 overlays one array of the contact holes 46 in this preferred embodiment. Further, the support substrate 50 serves to reinforce the silicon substrate 40, and the opening 52 of the support substrate 50 has, e.g., a circular shape or a rectangular shape. Moreover, the support substrate 50 is made of silicon, glass, ceramic or metal and the single layer silicon substrate 40 and the supporting substrate 50 are bonded to each other by a direct bonding, an anodic bonding, an intermediate layer bonding or the like.

Hereinafter, a method for manufacturing the contact substrate with the construction as described above will be described with reference to FIGS. 17 to 25.

FIGS. 17 to 25 are cross-sectional and perspective views illustrating a manufacturing process of the contact substrate performed in accordance with a preferred embodiment of the present invention.

First, a photoresist layer 42 is coated on the single layer silicon substrate 40 by a spin coating process as illustrated in FIG. 17.

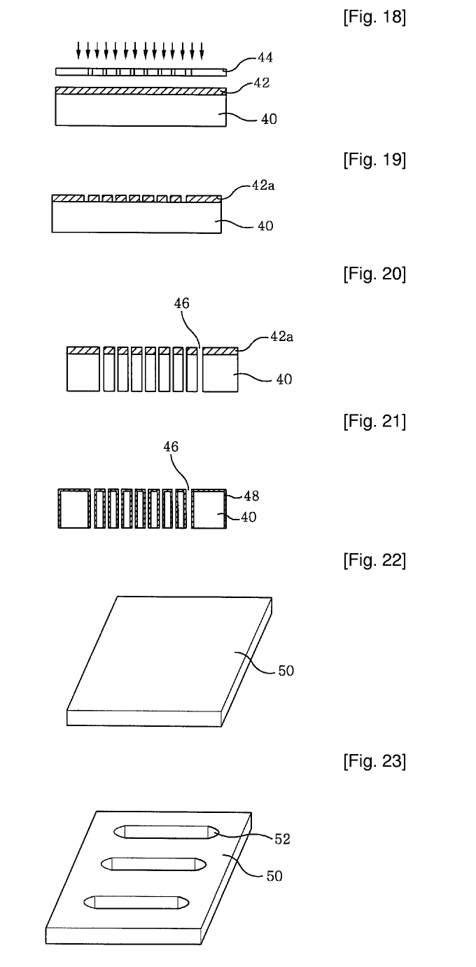

Next, as shown in FIG. 18, the photoresist layer 42 is exposed to a light through a plurality of contact hole patterns of a mask 44 disposed on an upper surface of the photoresist layer 42, by using an ultraviolet exposure unit, an X-ray exposure unit or an E-beam exposure unit.

Thereafter, by performing a developing process on the exposed photoresist layer 42, the patterned photoresist layer 42a is formed as shown in FIG. 19.

Next, as shown in FIG. 20, a deep silicon dry etching for MEMS applications is performed on the silicon substrate 40 exposed by the patterned photoresist layer 42a, thereby forming a plurality of the arrays of the contact holes 46 which penetrate the silicon substrate 40. At this time, as a mask for the deep silicon dry etching, a hard mask such as a metal, a silicon oxide film or the like may be used in addition to the patterned photoresist layer 42a.

In the ensuing step as shown in FIG. 21, the patterned photoresist layer 42a is removed by carrying out an ashing process. Further, by using a CVD process or the like, an insulating thin film 48, e.g., a silicon oxide film, a silicon nitride film or the like, is deposited on an entire upper surface of the silicon substrate 40 and inner surfaces of the plurality of the arrays of the contact holes 46.

Further, as illustrated in FIGS. 22 and 23, the supporting substrate 50, formed of silicon, glass, ceramic or metal, is mechanically processed by a milling or the like, thereby forming the openings 52 having an elliptic, a rectangular or another shape. In addition, the opening 52 is formed in such a way as to penetrate the supporting substrate 50.

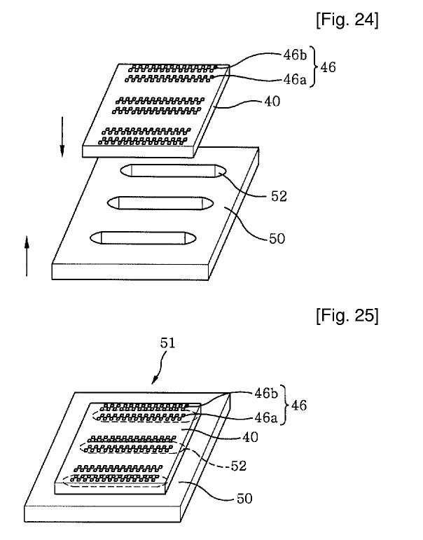

Thereafter, as shown in FIGS. 24 and 25, the silicon substrate 40 having the plurality of contact holes 46 and the supporting substrate 50 having the openings 52 are aligned and then bonded by using a direct bonding, an anodic bonding, an intermediate-layer bonding or the like, thereby manufacturing the contact substrate 51.

In the method for manufacturing a contact substrate performed in accordance with the preferred embodiment, the contact holes 46 with fine pitches are formed in the silicon substrate 40 deep silicon etching process for MEMS applications. Then, the supporting substrate 50 mechanically processed by a milling or the like is bonded thereunder in order to reinforce the silicon substrate 40. Therefore, it is easy to form contact holes with a finer pitch when compared with the prior art in which contact holes are formed by a mechanical process. And also, since in the present invention, the contact holes are formed in the single layer silicon substrate 40, the manufacturing process becomes simple in comparison with the prior art using a plural number of silicon substrates. For example, it is possible to solve problems of the prior art, e.g., an alignment problem occurring in stacking the plural number of silicon substrates of the silicon substrate having the holes of the same size formed therein.

Further, since the single layer silicon substrate 40 in which the contact holes 46 are formed is reinforced by the supporting substrate 50, it is possible to manufacture a 64 or higher para (or DUT (device under test)) probe card requiring contact holes with a fine pitch.

Further, the contact holes 46 can be arranged in a straight line at a predetermined pitch or in a zigzag manner. In case the contact holes 46 are arranged in the zigzag manner as shown in FIG. 16, in comparison with the contact holes arranged in a straight line, the gap of the contact holes 46 can become greater while reducing a vertical distance dv between the contact holes 46. Therefore, it is possible to manufacture a probe card with a fine pitch less than, e.g., 80 μm.

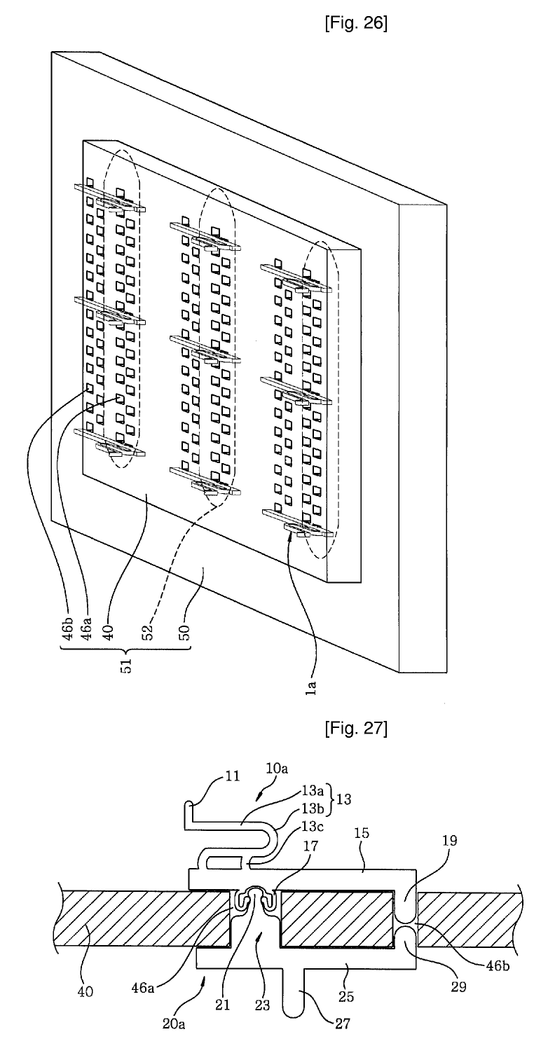

Hereinafter, a contact structure and its manufacture method will be described with reference to FIGS. 26 to 29.

FIGS. 26 to 29 are perspective and partial cross-sectional views of the contact structure (or a probe card) in accordance with preferred embodiments of the present invention. The contact structure is constituted by the contact substrate 51 and a plurality of, for example, the probes 1a installed in the contact substrate 51. The lower part 20a is inserted into the first contact hole 46 from the lower surface of the contact substrate 40. More specifically, the socket portion 23 of the lower part 20a is inserted into the first contact hole 46a and the align pin 29 is inserted into the second contact hole 46b. Then, the lower parts 20a are fixed to the contact substrate 40 by bonding, for example, sides of the lower base portion 25 thereto with a UV or heat cure epoxy or the like. Thereafter, as shown in FIG. 27, the socket portion 17 and the aligning pin 19 are inserted into the first contact hole 46a and the second contact hole 46b, respectively from the upper surface of the contact substrate 40, so that the plug portion 23 of the lower part 20a and the socket portion 17 of the upper part 20a are removably coupled to each other. At this time, an electrically conductive epoxy may be applied to the socket portion 17 of the upper part 10a so as to obtain the stronger connection between the socket portion 17 and the plug portion 23. However, by pulling the upper part 10a, it can be extracted from the lower part 20a without giving any damage to the lower part 20a.

Further, the first contact hole 46a, into which the socket portion 17 and the plug portion 23 are inserted, is formed in such a way as to have its width in a length direction of the probe 1a greater than that of the plug portion 23 by more than 10 μm and the second contact hole 46b, into which the aligning pins 19 and 29 are inserted, is formed in such a way as to have its width in the length direction of the probe greater than that of the probe aligning pin 19 or 29 by 3 to 10 μm. Therefore, the position error of the probe tip can be within a range of a few micrometers.

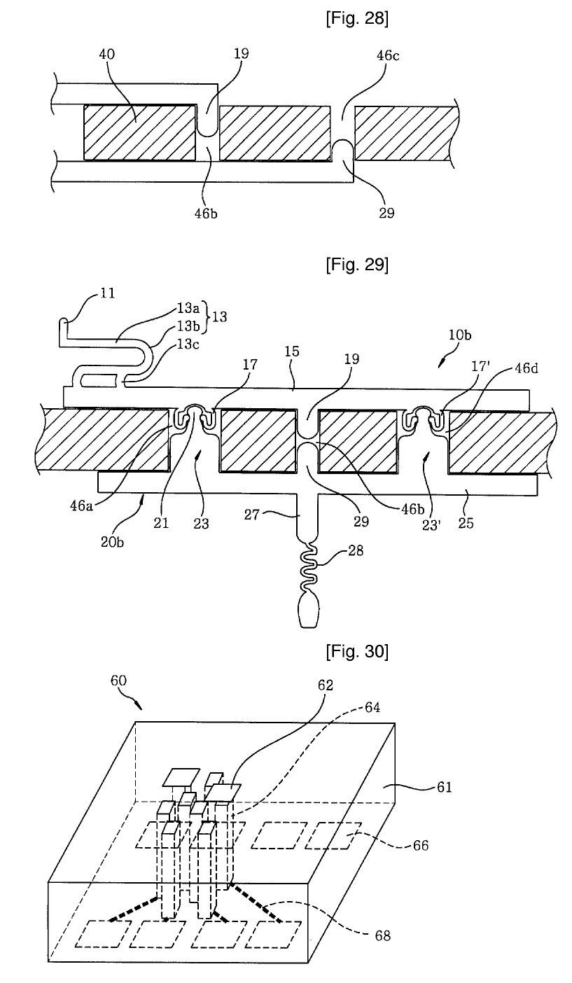

Additionally, as shown in FIG. 28, the silicon substrate 40 can further have third contact holes 46c. And the distance (d2−W) between the socket portion 17 and the aligning pin 19 is different from the distance d3 between the plug portion 23 and the aligning pin 29, the aligning pins 19 and 29 are inserted into different contact holes. In this embodiment, the aligning pin 19 is inserted into the second contact hole 46b and the aligning pin 29 is inserted into the third contact hole 46c.

Furthermore, in case where the probe 1b in accordance with the third preferred embodiment of the present invention is used in the contact structure, the silicon substrate 40 further has a third contact hole 46d for receiving the additional plug portion 23′ and the additional socket portion 17′ as shown in FIG. 29.

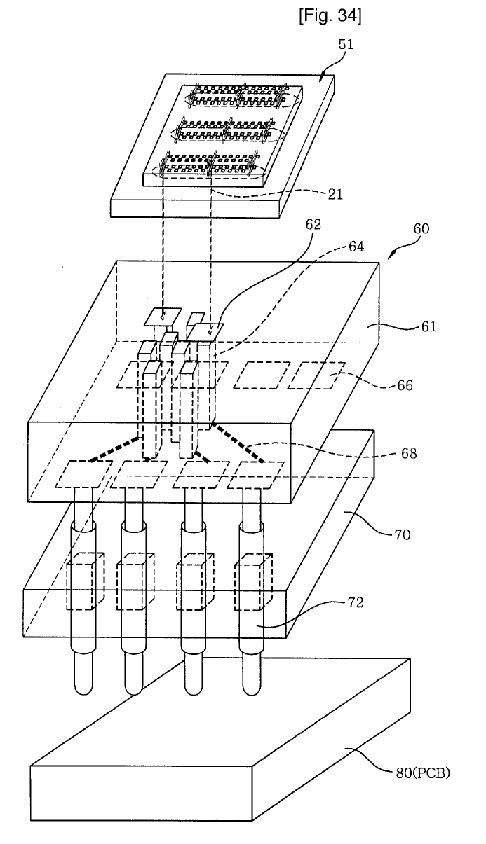

Hereinafter, a through hole space transformer for connecting the contact structure constituted by the contact substrate and a plurality of the probes to pogo pins installed in a pogo block 70 (see FIG. 34) in accordance with a preferred embodiment of the present invention will be described with reference to FIG. 30.

Referring to FIG. 30, there is illustrated a perspective view of the through hole space transformer in accordance with a preferred embodiment of the present invention. The through hole space transformer includes a stacked body 61 formed of a plurality of ceramic (e.g. Al₂O₃) sheets or silicon substrates; top pads 62, formed on an upper surface of the stacked body 61, for making contact with the connection pins 27 of the probes installed in the contact substrate 51; bottom pads 64, formed on a lower surface of the stacked body 61, for making contact with the pogo pins installed in the pogo block; a plurality of contacts 64, formed vertically from the corresponding top pads 62 to the lower surface of the stacked body 61 with an electrically conductive material; and a plurality of connection lines 68, formed on the lower surface of the stacked body 61, for electrically connecting the bottom pads 66 to the corresponding lower end of the contacts 64 exposed on the lower surface of the stacked body 61.

Further, the top pads 62 are disposed on the upper surface of the stacked body 61 at a relatively fine pitches while the bottom pads 66 are disposed on the lower surface of the stacked body 61 at a relatively coarse pitch. However, since the positions of the connection pins 27 of the probes can be modified depending on the positions of the upper pads 62, the top pads 62 can be disposed on the upper surface of the stacked body 61 at such a pitch that the contacts 64 are formed vertically in the stacked body 61.

Furthermore, since the contacts 64 are formed vertically in the stacked body 61 from the corresponding top pads 62 to the lower surface of the stacked body 61, the through hole space transformer has a good electrical characteristics.

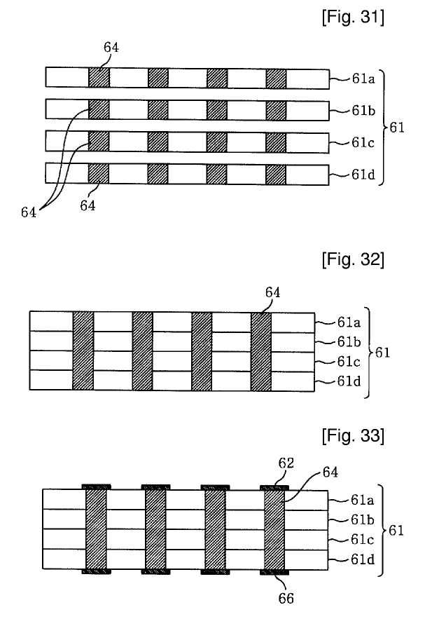

Hereinafter, a method for manufacturing the through hole space transformer 60 performed in accordance with a preferred embodiment of the present invention will be described with reference to FIGS. 31 to 33.

First, a plural number, for example 4, of ceramic sheets 61a to 61d are formed by a method of calender roll, doctor blade, extrusion molding or the like as shown in FIG. 31. Then, a plurality of through holes are formed in predetermined positions of the individual ceramic sheets 61a to 61d. Next, solder pasting processes are performed on the individual ceramic sheets 61a to 61d using Ag paste, so that the through holes are filled with the paste.

Thereafter, the plurality of the ceramic sheets 61a to 61d are stacked and sintered to form a sintered body as shown in FIG. 32.

In the ensuing step as shown in FIG. 33, a conductive layer (not shown) is formed on the upper surface of the sintered body 61 and a patterned photoresist layer (not shown) is formed on the conductive layer by performing a lithography process. Then, the top pads 62 are formed in openings of the patterned photoresist layer by a plating process utilizing Au, Cu or the like. Following the plating process, the patterned photoresist layer is removed. In case of necessity, connection lines (not shown) for electrically connecting the top pads 62 to the contacts 64 may be formed on the upper surface of the sintered body when the upper pads 62 are formed.

Next, a conductive layer (not shown) is formed on the lower surface of the sintered body and then a patterned photoresist layer (not shown) having openings formed therein for the bottom pads 66 and the connection lines 68 is formed on the conductive layer by performing a lithography process. Thereafter, the bottom pads 66 and the connection are formed by a plating process and then the patterned photoresist layer is removed. Alternatively, the bottom pads 66 and the connection lines 68 may be formed by a lift-off process and metal paste printing instead of utilizing the lithography and the plating process.

Hereinafter, a contact module in accordance with a preferred embodiment of the present invention will now be described in detail with reference to FIG. 34.

Referring to FIG. 34, there is illustrated an exploded, perspective view of the contact module which includes the contact substrate 51, the through hole space transformer 60 and a pogo pin block 70. The connection pins 27 of the probes 1 installed in the contact substrate 51 make contact with the top pads 62 of through hole space transformer 60. And the top pads 62 are connected to the bottom pads 66 via the contacts 64 and the connection lines 68. The bottom pads 66 make contact with pogo pins 72 installed in a pogo block 70, wherein the pogo pins 72 connect the bottom pads 66 of the through hole space transformer 60 to a printed circuit board (PCB) 80.

While the invention has been shown and described with respect to the preferred embodiments, it will be understood by those skilled in the art that various changes and modifications may be made without departing from the spirit and scope of the invention as defined in the following claims.

1. A probe for making electric contact with a contact target, comprising:
a first part including a first base portion and a socket portion formed on the first base portion; and
a second part including a second base portion and a plug portion formed on the second base portion,
wherein the plug portion is removably coupled to the socket portion.

2. The probe of claim 1, wherein the first part further includes an elastic portion formed on the first base portion and having a springable-shape, and a probe tip formed on a free end of the elastic portion.

3. The probe of claim 2, wherein the elastic portion is provided with a curved portion formed on the first base portion into an S-shape, and a bar portion extended horizontally or slantingly from a free end of the curved portion.

4. The probe of claim 3, wherein the first part further includes a supplementary pattern disposed between the first base portion and the curved portion and connecting the first base portion and the elastic portion.

5. The probe of claim 1, wherein the first part further includes an aligning pin formed on the first base portion.

6. The probe of claim 1, wherein the second part further includes a connection pin formed on the second base portion.

7. The probe of claim 6, wherein the second part further includes an aligning pin formed on the second base portion.

8. The probe of claim 6, wherein the connection pin has a connection elastic portion formed in a middle thereof.

9. The probe of claim 1, wherein the first part further includes another socket portion formed on the first base portion and the second part further includes another plug portion formed on the second base portion, wherein said another plug portion is removably connected to said another socket portion.

10. The probe of claim 1, wherein the second part further includes an elastic portion formed on the second base portion and having a springable-shape, and a probe tip formed on a free end of the elastic portion.

11. The probe of claim 10, wherein the elastic portion is provided with a curved portion formed on the second base portion into an S-shape, and a bar portion extended horizontally from a free end of the curved portion.

12. The probe of claim 11, wherein the second part further includes a supplementary pattern disposed between the second base portion and the curved portion and connecting the second base portion and the elastic portion.

13. The probe of claim 1, wherein the second part further includes an aligning pin formed on the second base portion.

14. The probe of claim 1, wherein the first part further includes a connection pin formed on the first base portion.

15. The probe of claim 14, wherein the first part further includes an aligning pin formed on the first base portion.

16. The probe of claim 14, wherein the connection pin has a connection elastic portion formed in a middle thereof.

17. The probe of claim 2 or 10, wherein an end portion of the probe tip is formed in a truncated pyramid shape.

18. The probe of claim 2 or 10, wherein a relative position of the socket portion with respect to the probe tip is modified in such a manner that the probe tips are arranged in a line when a plurality of the probes are installed in a contact structure having contact holes arranged in a zigzag manner, whereby the probe is compatible with contact targets having a fine pitch.

19. The probe of claim 6 or 14, wherein a relative position of the connection pin with respect to the plug portion is modified in such a manner that the connection pins allow contacts of a space transformer to be formed straightly therein when a contact structure in which a plurality of the probes are installed is combined with the space transformer.

20. A method for manufacturing a probe, comprising the steps of:
forming a conductive layer on a semiconductor substrate;
forming on the conductive layer a pattern layer in which a first group of openings, each being formed in a shape of a first part having a socket portion, and a second group of openings, each being formed in a shape of a second part having a plug portion, are formed, the first group of openings being connected to a first tree opening, the second group of openings being connected to a second tree opening;
forming a probe structure on an upper surface of the conductive layer exposed through the pattern layer by performing a plating process; and
removing the pattern layer, the semiconductor substrate and the conductive layer.

21. A method for manufacturing a probe, comprising the steps of:
forming a conductive layer on a semiconductor substrate;
forming on the conductive layer a pattern layer which has a first group of patterns, each being formed in a shape of a first part having a socket portion, and a second group of patterns, each being formed in a shape of a second part having a plug portion, the first group of patterns being connected to a first tree patterns, the second group of patterns being connected to a second tree pattern;
forming a probe structure by patterning the conductive layer covered by the pattern layer; and
removing the pattern layer and the semiconductor substrate,
wherein the pattern layer serves as an etch mask when the conductive layer is patterned.

22. The method of claim 20 or 21, further comprising the step of:
after removing the semiconductor substrate, separating a first group of sub-patterns and a second group of sub-patterns from a first and a second tree structure,
wherein the probe structure has the first group of sub-structures, each being formed in a shape of the first part having a socket portion, and the second group of sub-structures, each being formed in a shape of a second part having a plug portion, the first and the second group being connected to the first and the second tree structure, respectively,

23. The method of claim 22, further comprising the step of: before separating the first group of sub-patterns and the second group of sub-patterns from the first and the second tree structure, processing end portions of probe tips of the first group of sub-patterns in a truncated pyramid shape.

24. The method of claim 23, wherein the processing employs a wet etching process or a mechanical grinding process.

25. A method for manufacturing a contact module, comprising the steps of:
inserting a first part of a probe, having a first base portion, a socket portion formed on the first base portion, and a second part of the probe, having a second base portion, a plug portion formed on the second base portion and a connection pin formed on the second base portion, into an upper and a lower portion of a contact hole of a contact substrate, respectively so that the first part is removably coupled to the second part; and
mounting a through hole space transformer on the connection pin of the probe.

26. The method of claim 25, wherein the contract substrate is formed by bonding a semiconductor substrate and a supporting substrate.

27. The method of claim 26, wherein the semiconductor substrate and the supporting substrate are bonded in such a manner that a group of contact holes formed in the semiconductor substrate are overlaid with an opening formed in the supporting substrate.

28. The method of claim 27, further comprising the step of: after forming the contact holes, depositing an insulating thin film on an upper surface of the semi-conductor substrate and inner surfaces of the contact holes.

29. The method of claim 27, wherein the opening of the supporting substrate is formed in an elliptic or a rectangular shape.

30. The method of claim 27 or 28, wherein the contact holes are arranged regularly at a predetermined pitch therebetween or in a zigzag manner.

31. The method of any one of claims 26 to 28, wherein the semiconductor substrate is constituted by a single layer silicon substrate.

32. The method of claim 26 or 27, wherein the supporting substrate is made of silicon, glass, ceramic or metal.

33. The method of claim 25, wherein when the socket portion and the plug portion are inserted into the contact hole of the contact substrate, an aligning pin formed on the first or the second base portion is inserted into another contact hole adjacent to the contact hole.

34. The method of claim 25, wherein a method for manufacturing the through hole space transformer includes the steps of:
forming a plurality of through holes in predetermined position of a plurality of substrates in such a manner that through holes formed in the substrate are overlaid by through holes formed in another substrate when the substrate is overlaid by said another substrate;
forming contacts by filling the through holes with metal;
stacking the plurality of substrates;
sintering the stacked substrates;
forming on an uppermost surface of the sintered substrates top pads for making contact with a connection pin of the probe; and
forming on an lowermost surface of the sintered substrates bottom pads for making contact with pogo pins,
wherein the positions of the top pads correspond to the connection pins of the probe.

35. The method of claim 34, wherein the top pads and the bottom pads are formed by utilizing a lithography and a plating process.

36. The method of claim 34, wherein the top pads and the bottom pads are formed by utilizing a lift-off process and a metal paste printing.
